(19) United States
(12) Patent Application Publication
(10) Pub. No.: US 2024/0162039 A1
(43) Pub. Date: May 16, 2024

(54) METHOD FOR MANUFACTURING PHOTOMASK AND METHOD FOR MANUFACTURING SEMICONDUCTOR DEVICE USING THE SAME

(71) Applicant: Samsung Electronics Co., Ltd., Suwon-si (KR)

(72) Inventors: Bon Hyun GU, Suwon-si (KR); Soo Yong LEE, Suwon-si (KR); Bong Cheol KIM, Suwon-si (KR); Sang Ho LEE, Suwon-si (KR)

(73) Assignee: Samsung Electronics Co., Ltd., Suwon-si (KR)

(21) Appl. No.: 18/483,176

(22) Filed: Oct. 9, 2023

(30) Foreign Application Priority Data
Nov. 14, 2022 (KR) 10-2022-0151453

(51) Int. Cl. H01L 21/027; H01L 21/56; H01L 21/66

(52) U.S. Cl. CPC H01L 21/0274; H01L 21/565; H01L 22/12

(57) ABSTRACT

Provided is a method for manufacturing a photomask. The method comprises providing a pre-photomask, the pre-photomask including a first area, a second area configured to perform a first duty correction, and a third area configured to perform a second duty correction; forming a pre-photoresist pattern using the pre-photomask such that the pre-photoresist pattern has a stepped shape having at least three steps in a cross-sectional view of the pre-photoresist pattern; analyzing a profile of the pre-photoresist pattern in the cross-sectional view; and inserting an auxiliary pattern into at least one of the first to third areas, based on a result of the analyzing of the profile of the pre-photoresist pattern.

### CROSS-REFERENCE TO RELATED APPLICATION

This application claims priority from Korean Patent Application No. 10-2022-0151453 filed on Nov. 14, 2022 in the Korean Intellectual Property Office, and all the benefits accruing therefrom under 35 U.S.C. 119, the contents of which in its entirety are herein incorporated by reference.

### BACKGROUND

### Field

The present disclosure relates to a method for manufacturing a photomask for manufacturing a semiconductor device in which a manufacturing time and a manufacturing cost are reduced, and a method for manufacturing a semiconductor device using the photomask.

### Description of Related Art

It is required to increase the degree of integration of semiconductor devices in order to meet the performance and price requirements for semiconductor devices demanded by consumers. The integration of semiconductor devices in electronic apparatus is an important factor in determining a price of a product. Thus, an increased integration thereof is particularly required. An integration of a two-dimensional (2D) or planar semiconductor device is largely determined based on an area occupied by a unit memory cell, and thus is greatly affected by a level of a fine pattern formation skill. However, ultra-expensive equipment is required for formation of fine patterns. Thus, although the integration of the 2D semiconductor device is increasing, this increase is limited. Accordingly, a three-dimensional (3D) semiconductor device having 3D arranged memory cells has been proposed.

In this regard, in a process of manufacturing the 3D semiconductor device, an exposure process and/or an etching process may be performed multiple times to manufacture a stepped cell structure. As the number of the processes as performed increases and the number of stacks increases, an error may occur at a boundary between steps.

### SUMMARY

A technical purpose of the present disclosure is to provide a method for manufacturing a photomask used for manufacturing a semiconductor device in which a manufacturing time and a manufacturing cost are reduced.

Another technical purpose of the present disclosure is to provide a method for manufacturing a semiconductor device in which a manufacturing time and a manufacturing cost are reduced.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

According to an aspect of the present disclosure, there is provided a method for manufacturing a photomask, the method comprising, providing a pre-photomask, the pre-photomask including a first area, a second area configured to perform a first duty correction, and a third area configured to perform a second duty correction; forming a pre-photoresist pattern using the pre-photomask such that the pre-photoresist pattern has a stepped shape having at least three steps in a cross-sectional view of the pre-photoresist pattern; analyzing a profile of the pre-photoresist pattern in the cross-sectional view; and inserting an auxiliary pattern into at least one of the first to third areas, based on a result of the analyzing of the profile of the pre-photoresist pattern.

According to another aspect of the present disclosure, there is provided a method for manufacturing a photomask, the method comprising, providing a pre-photoresist; providing a pre-photomask over the pre-photoresist, the pre-photomask including at least a first area configured to perform a first duty correction and a second area configured to perform a second duty correction; performing an exposure process on the pre-photoresist using the pre-photomask to form a pre-photoresist pattern, wherein the pre-photoresist pattern includes a first portion formed using the first area and a second portion formed using the second area such that, in a cross-sectional view of the pre-photoresist pattern, the first area includes a first sub-portion having a constant vertical dimension, and a second sub-portion having a varying vertical dimension; analyzing a profile of the second sub-portion of the pre-photoresist pattern; and inserting an auxiliary pattern into the first area based on a result of the analyzing the profile of the second sub-portion.

According to another aspect of the present disclosure, there is provided a method for manufacturing a semiconductor device, the method comprising, manufacturing a photomask; forming a photoresist pattern using the photomask such that the photoresist pattern has a stepped shape having at least three steps in a cross-sectional view of the photoresist pattern; forming a step-shaped mold structure using the photoresist pattern as an etching mask, wherein the mold structure includes a plurality of mold insulating films and a plurality of gate electrodes alternately stacked on top of each other; and forming a channel structure extending through the mold structure and connected to the gate electrodes, wherein the manufacturing of the photomask includes providing a pre-photomask including a first area, a second area configured to perform first duty correction, and a third area configured to perform a second duty correction, forming a pre-photoresist pattern using the pre-photomask such that the pre-photoresist pattern has a stepped shape having at least three steps in a cross-sectional view of the pre-photoresist pattern, analyzing a profile of the pre-photoresist pattern in the cross-sectional view inserting an auxiliary pattern into at least one of the first to third areas based on a result of the analyzing of the profile of the pre-photoresist pattern, and performing a fourth duty correction on at least one of the first to third areas using the pre-photoresist pattern with the inserted auxiliary pattern.

### BRIEF DESCRIPTION OF DRAWINGS

The above and other aspects and features of the present disclosure will become more apparent by describing in detail embodiments thereof with reference to the attached drawings, in which:

FIG. 1 is an illustrative flow chart of a method for manufacturing a photomask according to some embodiments of the present disclosure.

FIGS. 2 to 8 are diagrams of intermediate structures corresponding to intermediate steps for illustrating a method for manufacturing a photomask according to some embodiments.

FIG. 9 is an illustrative flow chart of a method for manufacturing a photomask according to some further embodiments of the present disclosure.

FIGS. 10 and 11 are views for illustrating a method for manufacturing a photomask according to some further embodiments.

FIG. 12 is an illustrative flowchart of a method for manufacturing a semiconductor device according to some embodiments of the present disclosure.

FIGS. 13 to 19 are intermediate views for illustrating a method for manufacturing a semiconductor device according to some embodiments.

FIG. 20 is an illustrative block diagram for illustrating a semiconductor device in accordance with some embodiments.

FIG. 21 is an illustrative circuit diagram for illustrating a semiconductor device according to some embodiments.

FIG. 22 is an illustrative cross-sectional view for illustrating a semiconductor device according to some embodiments.

FIG. 23 is an enlarged view of an S area in FIG. 22.

FIG. 24 is an illustrative block diagram for illustrating an electronic system in accordance with some embodiments.

FIG. 25 is an illustrative perspective view for illustrating an electronic system in accordance with some embodiments.

FIG. 26 is a schematic cross-sectional view taken along a line I-I in FIG. 25.

### DETAILED DESCRIPTIONS

In the present specification, although terms such as first, second, top and bottom are used to describe various elements or components, it goes without saying that these elements or components are not limited by these terms. These terms are only used to distinguish a single element or component from other elements or components. Therefore, it goes without saying that a first element or component referred to below may be a second element or component within the present disclosure. In addition, it goes without saying that a lower element or component referred to below may be an upper element or component within the present disclosure. For example, it will be understood that such spatially relative terms are intended to encompass different orientations of the device in use or operation in addition to the orientation depicted in the figures, and that the device may be otherwise oriented (rotated 90 degrees or at other orientations) and the spatially relative terms used herein interpreted accordingly.

Hereinafter, embodiments according to the present disclosure will be described with reference to the accompanying drawings, wherein like reference numerals refer to like elements throughout. In the drawings, a size of each component in the drawings may be exaggerated for clarity and convenience of description. Meanwhile, the embodiments described below are merely example, and various modifications are possible from these embodiments. When the terms “about” or “substantially” are used in this specification in connection with a value, it is intended that the associated value includes a manufacturing tolerance (e.g., ±10%) around the stated value. Further, regardless of whether values are modified as “about” or “substantially,” it will be understood that these values should be construed as including a manufacturing or operational tolerance (e.g., ±10%) around the stated values.

Also, in the specification, functional elements may be realized by processing circuitry such as hardware, software, or a combination of hardware and software. For example, the processing circuitry, more specifically, may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.; and/or the processing circuitry may include electrical components such as at least one of transistors, resistors, capacitors, etc., and/or electronic circuits including said components.

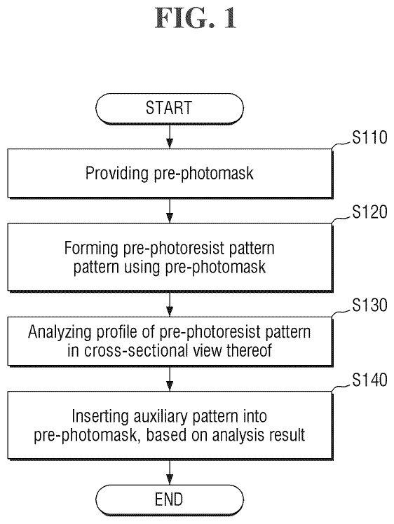

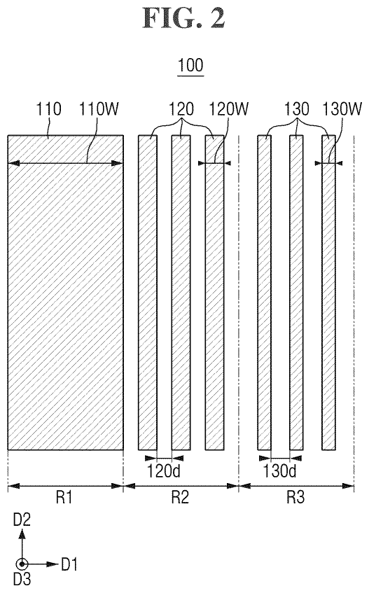

Hereinafter, a method for manufacturing a photomask according to some embodiments is described with reference to FIGS. 1 to 8. FIG. 1 is an illustrative flow chart of a method for manufacturing a photomask according to some embodiments of the present disclosure. FIGS. 2 to 8 are diagrams of intermediate structures corresponding to intermediate steps for illustrating a method for manufacturing a photomask according to some embodiments.

First, referring to FIG. 1, a method for manufacturing a photomask according to some embodiments may include providing a pre-photomask in S110, forming a pre-photoresist pattern using the pre-photomask in S120, analyzing a profile of the pre-photoresist pattern in a cross-sectional view in S130, and inserting an auxiliary pattern into the pre-photomask based on the analysis result in S140.

For example, referring to FIGS. 1 and 2, a pre-photomask 100 may be provided in S110. For reference, FIG. 2 may be an illustrative plan view of the pre-photomask 100.

The pre-photomask 100 may include a first area R1, a second area R2, and a third area R3. The first area R1, the second area R2, and the third area R3 may be sequentially arranged in the first direction D1. The first direction D1 may be a direction parallel to an upper surface on which a duty correction is to be performed. In some embodiments, the first area R1 may be an area on which duty correction is not performed. The second area R2 may be an area on which a first duty correction is performed. The third area R3 may be an area on which a second duty correction is performed. As use herein, the term “duty correction” may mean adjusting a size of an area in which light transmits through the photomask.

In some embodiments, the first area R1 may include a first pattern 110. The first pattern 110 may fill an entirety of the first area R1. The second area R2 may include a second pattern 120. The second pattern 120 does not fill an entirety of the second area R2. The second pattern 120 may include at least one second pattern. The second patterns 120 may be spaced apart from each other in the first direction D1. Each of the second patterns 120 may extend in the second direction D2. The third pattern 130 does not fill an entirety of the third area R3. The third pattern 130 may include at least one third pattern. The third patterns 130 may be spaced apart from each other in the first direction D1. Each of the third patterns 130 may extend in the second direction D2.

As used herein, the second direction D2 may be parallel the upper surface such that the first direction D1 and the second direction D2 intersect each other. Further, a third direction D3 may be perpendicular to the upper surface and intersect the first direction D1 and the second direction D2. In at least some embodiments, the first direction D1, the second direction D2, and the third direction D3 may be substantially perpendicular to each other.

In some embodiments, a first width 110W in the first direction D1 of the first pattern 110 is greater than a second width 120W in the first direction D1 of each of the second patterns 120. In at least some embodiments, the first width 110W in the first direction D1 defines the first area R1 in the first direction D1. Further, the first width 110W in the first direction D1 of the first pattern 110 is greater than a sum of the second widths 120W in the first direction D1 of the second patterns 120. In other words, while the first pattern 110 does not expose the first area R1, the second pattern 120 may expose at least a portion of the second area R2.

A third width 130W in the first direction D1 of each of the third patterns 130 is smaller than the second width 120W in the first direction D1 of each of the second patterns 120. Further, a sum of the third widths 130W in the first direction D1 of the third patterns 130 is smaller than the sum of the second widths 120W in the first direction D1 of the second patterns 120. In other words, a size of an area exposed by the third pattern 130 is greater than a size of an area exposed by the second pattern 120 and, therefore, a size of an area not covered with the second pattern 120 is smaller than a size of the area not covered with the third pattern 130. Further, a spacing 120d by which the second patterns 120 are spaced from each other in the first direction D1 may be smaller than a spacing 130d by which the third patterns 130 are spaced from each other in the first direction D1. However, the present disclosure is not limited thereto.

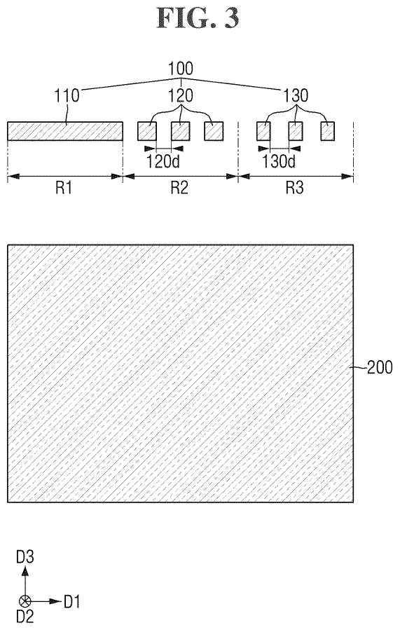

Referring to FIG. 3, a pre-photoresist 200 may be provided. The pre-photomask 100 may be disposed on the pre-photoresist 200. The pre-photoresist 200 and the pre-photomask 100 may be spaced apart from each other in the third direction D3. As described above, the first pattern 110 does not expose a portion of the pre-photoresist 200; the second pattern 120 of the pre-photomask 100 exposes a portion of the pre-photoresist 200; and the third pattern 130 of the pre-photomask 100 exposes a greater portion of the pre-photoresist 200.

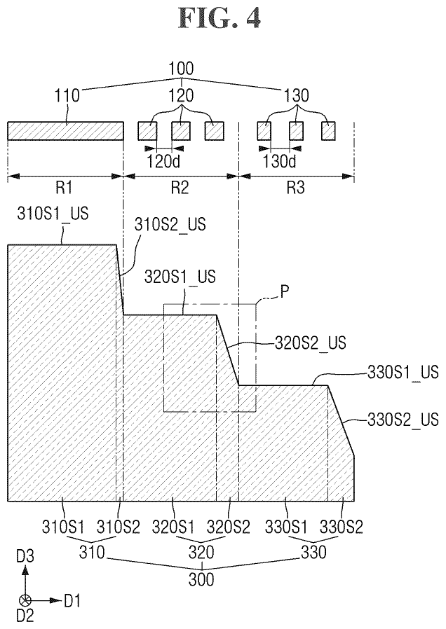

Referring to FIG. 4, a pre-photoresist pattern 300 may be formed using the pre-photomask 100 (in S120 in FIG. 1). The pre-photoresist pattern 300 may be formed by performing an exposure process on the pre-photoresist (200 of FIG. 3) using the pre-photomask 100 as a mask. As described above, each of the second area R2 and the third area R3 of the pre-photomask 100 may be an area on which the duty correction is performed. Thus, the second pattern 120 of the pre-photomask 100 exposes a portion of the pre-photoresist 200. The third pattern 130 of the pre-photomask 100 exposes a portion of the pre-photoresist 200.

An area of the pre-photomask 100 not covered with the second pattern 120 is smaller than an area of the pre-photomask 100 not covered with the third pattern 130. Further, an area of the pre-photomask 100 not covered with the first pattern 110 is smaller than the area of the pre-photomask 100 not covered with the second pattern 120. Accordingly, an area size of a portion of the pre-photoresist pattern 300 formed using the first area R1 of the pre-photomask 100 is greater than an area size of a portion of the pre-photoresist pattern 300 formed using the second area R2 of the pre-photomask 100 when viewed in cross-section. Further, the area size of the portion of the pre-photoresist pattern 300 formed using the second area R2 of the pre-photomask 100 is greater than an area size of a portion of the pre-photoresist pattern 300 formed using the third area R3 of the pre-photomask 100 when viewed in cross-section.

More specifically, a shape of the pre-photoresist pattern 300 may be a stepped shape in a cross-sectional view. For example, in a cross-sectional view, the shape of the pre-photoresist pattern 300 may be a stepped shape having at least three steps. However, the present disclosure is not limited thereto.

In some embodiments, the pre-photoresist pattern 300 may include first to third portions 310, 320, and 330. The first to third portions 310, 320, and 330 of the pre-photoresist pattern 300 may be sequentially arranged in the first direction D1. The second portion 320 may be disposed between the first portion 310 and the third portion 330.

The first portion 310 of the pre-photoresist pattern 300 may be formed using the first area R1 of the pre-photomask 100. For example, the first portion 310 of the pre-photoresist pattern 300 may be formed by performing an exposure process on the first pattern 110. The second portion 320 of the pre-photoresist pattern 300 may be formed using the second area R2 of the pre-photomask 100. For example, the second portion 320 of the pre-photoresist pattern 300 may be formed by performing an exposure process on the second pattern 120. The third portion 330 of the pre-photoresist pattern 300 may be formed using the third area R3 of the pre-photomask 100. For example, the third portion 330 of the pre-photoresist pattern 300 may be formed by performing an exposure process on the third pattern 130.

A vertical dimension in the third direction D3 of the first portion 310 of the pre-photoresist pattern 300 is greater than a vertical dimension in the third direction D3 of the second portion 320 of the pre-photoresist pattern 300. Further, a vertical dimension in the third direction D3 of the second portion 320 of the pre-photoresist pattern 300 is greater than the vertical dimension in the third direction D3 of the third portion 330 of the pre-photoresist pattern 300.

In some embodiments, the first portion 310 of the pre-photoresist pattern 300 may include a first sub-portion 310S1 having a constant vertical dimension and a second sub-portion 310S2 having a varying vertical dimension. For example, a vertical dimension from a bottom surface of the first portion 310 of the pre-photoresist pattern 300 to a top surface 310S1_US of the first sub-portion 310S1 of the first portion 310 of the pre-photoresist pattern 300 is constant, while, a vertical dimension from the bottom surface of the first portion 310 of the pre-photoresist pattern 300 to a top surface 310S2_US of the second sub-portion 310S2 of the first portion 310 of the pre-photoresist pattern 300 is not constant. For example, the vertical dimension from the bottom surface of the first portion 310 of the pre-photoresist pattern 300 to the top surface 310S2_US of the second sub-portion 310S2 of the pre-photoresist pattern 300 may gradually decrease as the second sub-portion 310S2 extends from the first sub-portion 310S1 of the first portion 310 toward the second portion 320.

The second portion 320 of the pre-photoresist pattern 300 may include a third sub-portion 320S1 having a constant vertical dimension and a fourth sub-portion 320S2 having a varying vertical dimension. For example, a vertical dimension from a bottom surface of the second portion 320 of the pre-photoresist pattern 300 to a top surface 320S1_US of the third sub-portion 320S1 of the pre-photoresist pattern 300 is constant, while a vertical dimension from the bottom surface of the second portion 320 of the pre-photoresist pattern 300 to a top surface 320S2_US of the fourth sub-portion 320S2 of the pre-photoresist pattern 300 is not constant. For example, the vertical dimension from the bottom surface of the second portion 320 of the pre-photoresist pattern 300 to the top surface 320S2_US of the fourth sub-portion 320S2 of the pre-photoresist pattern 300 may decrease gradually as the fourth sub-portion 320S2 extends in the first direction D1 from the first portion 310 to the third portion 330.

The third portion 330 of the pre-photoresist pattern 300 may include a fifth sub-portion 330S1 having a constant vertical dimension and a sixth sub-portion 330S2 having a varying vertical dimension. For example, a vertical dimension from the bottom surface of the third portion 330 of the pre-photoresist pattern 300 to a top surface 330S1_US of the fifth sub-portion 330S1 of the pre-photoresist pattern 300 is constant, while a vertical dimension from the bottom surface of the third portion 330 of the pre-photoresist pattern 300 to a top surface 330S2_US of the sixth sub-portion 330S2 of the pre-photoresist pattern 300 is not constant. For example, the vertical dimension from the bottom surface of the third portion 330 of the pre-photoresist pattern 300 to the top surface 330S2_US of the sixth sub-portion 330S2 of the pre-photoresist pattern 300 gradually decreases as the sixth sub-portion 330S2 extends away from the fifth sub-portion 330S1 in the first direction D1.

In some embodiments, a profile of the pre-photoresist pattern 300 in a cross-sectional view may be analyzed (in S130 in FIG. 1). In a cross-sectional view, a profile of a top surface of the pre-photoresist pattern 300 may include profiles of the top surface 310S1_US of the first sub-portion 310S1 of the pre-photoresist pattern 300, the top surface 310S2_US of the second sub-portion 310S2, the top surface 320S1_US of the third sub-portion 320S1, the top surface 320S2_US of the fourth sub-portion 320S2, the top surface 330S1_US of the fifth sub-portion 330S1, and the top surface 330S2_US of the sixth sub-portion 330S2.

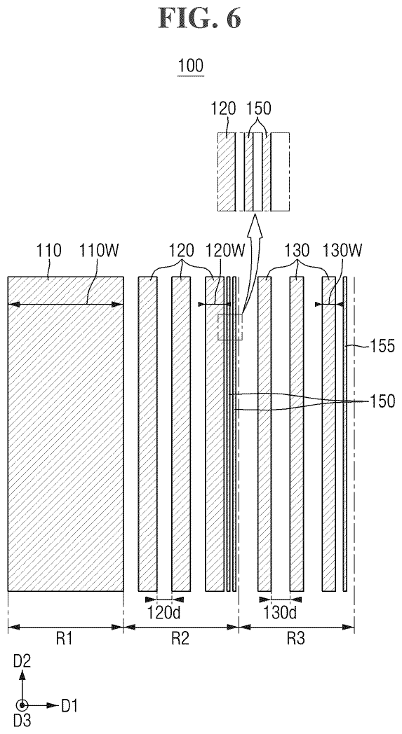

An auxiliary pattern may be inserted into the pre-photomask based on the analysis result of the profile. The auxiliary pattern will be described later with reference to FIG. 6.

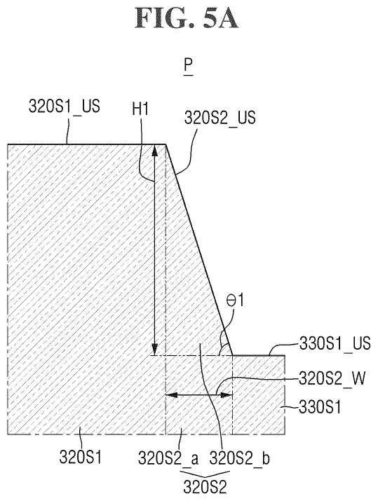

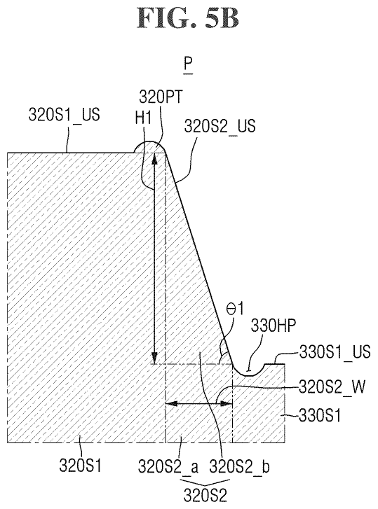

Analyzing the profile of the pre-photoresist pattern 300 in the cross-sectional view may include analyzing profiles of each of the top surface 310S2_US of the second sub-portion 310S2, the top surface 320S2_US of the fourth sub-portion 320S2, and/or the top surface 330S2_US of the sixth sub-portion 330S2. For reference, FIGS. 5A and 5B are enlarged views of an area P in FIG. 4 and are provided as an example. Analyzing the profile of the top surface 310S2_US of the second sub-portion 310S2, analyzing the profile of the top surface 320S2_US of the fourth sub-portion 320S2, and analyzing the profile of the top surface 330S2_US of the sixth sub-portion 330S2 may be substantially similar and/or identical to each other. Thus, hereinafter, only the analysis of the profile of the top surface 320S2_US of the fourth sub-portion 320S2 is described.

For example, referring to FIGS. 5A and 5B, the fourth sub-portion 320S2 of the second portion 320 of the pre-photoresist pattern 300 may include a lower portion 320S2_a and an upper portion 320S2_b.

The upper portion 320S2_b of the fourth sub-portion 320S2 may be disposed on the lower portion 320S2_a of the fourth sub-portion 320S2. The top surface 320S2_US of the fourth sub-portion 320S2 may be a top surface of the upper portion 320S2_b of the fourth sub-portion 320S2.

The lower portion 320S2_a of the fourth sub-portion 320S2 may overlap the third portion 330 in the first direction D1. The lower portion 320S2_a of the fourth sub-portion 320S2 may overlap the fifth sub-portion 330S1 of the third portion 330 in the first direction D1. The upper portion 320S2_b of the fourth sub-portion 320S2 may not overlap the third portion 330 in the first direction D1. The upper portion 320S2_b of the fourth sub-portion 320S2 may not overlap with the fifth sub-portion 330S1 of the third portion 330 in the first direction D1.

In some embodiments, the top surface 320S2_US of the fourth sub-portion 320S2 does not extend parallel to the third direction D3. The top surface 320S2_US of the fourth sub-portion 320S2 may extend in a direction between the first direction D1 and the third direction D3. For example, the top surface 320S2_US of the fourth sub-portion 320S2 may have a slope with respect to the top surface 330S1_US of the fifth sub-portion 330S1. In at least one example, a first angle θ1 defined between the top surface 320S2_US of the fourth sub-portion 320S2 and an extension line from the top surface 330S1_US of the fifth sub-portion 330S1 may be greater than 0° and smaller than 90°. The first angle θ1 may be an acute angle, and may also be referred to as a first internal angle. The first angle θ1 may also be determined from the relationship between the top surface 320S2_US of the fourth sub-portion 320S2 and the top surface 330S1_US of the fifth sub-portion 330S1, by subtracting the outer angle from 180°. Therefore, in at least one example, the outer angle may be greater than 90° and smaller than 180°.

In some embodiments, the slope of the top surface 320S2_US of the fourth sub-portion 320S2 may be defined as a ratio of a relative vertical dimension H1 of the upper portion 320S2_b of the fourth sub-portion 320S2 to a width 320S2_W of the lower portion 320S2_a of the fourth sub-portion 320S2. The relative vertical dimension H1 of the upper portion 320S2_b may refer to a vertical dimension in the third direction D3 from a point where the top surface 320S1_US of the third sub-portion 320S1 and the top surface 320S2_US of the fourth sub-portion 320S2 meet each other to the extension line from the top surface 330S1_US of the fifth sub-portion 330S1. In this regard, the extension line from the top surface 330S1_US of the fifth sub-portion 330S1 may define a boundary face between the upper portion 320S2_b and the lower portion 320S2_a of the fourth sub-portion 320S2. The relative vertical dimension H1 may also be referred to as the height of the upper portion 320S2_b.

In some embodiments, the number of auxiliary patterns to be inserted may be determined based on the slope of the top surface 320S2_US of the fourth sub-portion 320S2. For example, as the slope of the top surface 320S2_US of the fourth sub-portion 320S2 decreases, the number of the auxiliary patterns to be inserted may increase. More specifically, the number of auxiliary patterns to be inserted when the first angle θ1 is to be 60° is greater than the number of auxiliary patterns to be inserted when the first angle θ1 is to be 70°. Further, as the ratio of the maximum vertical dimension H1 of the upper portion 320S2_b of the fourth sub-portion 320S2 to the width 320S2_W of the lower portion 320S2_a of the fourth sub-portion 320S2 is smaller, the number of auxiliary patterns to be inserted may increase. More specifically, the number of auxiliary patterns to be inserted when the ratio is 2 is greater than the number of auxiliary patterns to be inserted when the ratio is 3.

Conversely, as the slope of the top surface 320S2_US of the fourth sub-portion 320S2 increases, the number of auxiliary patterns to be inserted may decrease. In at least one example, when the first angle θ1 is substantially equal to 90°, the auxiliary pattern may not be inserted. In other words, when the ratio of the maximum vertical dimension H1 of the upper portion 320S2_b of the fourth sub-portion 320S2 to the width 320S2_W of the lower portion 320S2_a of the fourth sub-portion 320S2 is large, the auxiliary pattern may not be inserted.

In FIG. 5B, the second portion 320 of the pre-photoresist pattern 300 according to some embodiments may further include a protrusion 320PT and/or a depression 330HP.

The protrusion 320PT may protrude from the top surface 320S1_US of the third sub-portion 320S1 of the second portion 320 of the pre-photoresist pattern 300 in the third direction D3. The depression 330HP may be recessed in the third direction D3 from the top surface 330S1_US of the fifth sub-portion 330S1 of the third portion 330 of the pre-photoresist pattern 300.

The number of auxiliary patterns to be inserted may be determined based on a size of the protrusion 320PT and a size of the depression 320HP. For example, the number of auxiliary patterns to be inserted may be determined based on a vertical dimension in the third direction D3 of the protrusion 320PT and/or a depth in the third direction D3 of the depression 320HP. In at least one example, the number of auxiliary patterns to be inserted when the size of the protrusion 320PT is larger may be smaller than that when the size of the protrusion 320PT is smaller. The number of auxiliary patterns to be inserted when the size of the depression 320HP is larger may be larger than the number of auxiliary patterns to be inserted when the size of the depression 320HP is smaller.

Inserting the auxiliary patterns allows the top surface 310S1_US of the first sub-portion 310S1, the top surface 320S1_US of the third sub-portion 320S1, and the top surface 330S1_US of the fifth sub-portion 330S1 to further extend in the first direction D1, and allows the top surface 310S2_US of the second sub-portion 310S2, the top surface 320S2_US of the fourth sub-portion 320S2, and the top surface 330S2_US of the sixth sub-portion 330S2 to further extend in the third direction D3. However, the present disclosure is not limited thereto.

Referring to FIG. 6, a first auxiliary pattern 150 and a second auxiliary pattern 155 is inserted into the pre-photomask 100 based on analysis of the profile of the pre-photoresist pattern (in S140 of FIG. 1). For example, the first auxiliary pattern 150 may be inserted into the second area R2, and the second auxiliary pattern 155 may be inserted into the third area R3. The first auxiliary pattern 150 may be inserted into an area corresponding to the fourth sub-area 320S2. The second auxiliary pattern 155 may be inserted into an area corresponding to the sixth sub-area 330S2.

In at least one example, the first auxiliary pattern 150 is disposed between the second patterns 120 and/or between the second pattern 120 and the third pattern 130. In at least one example, the second auxiliary pattern 155 is disposed between the third patterns 130 and/or between one of the third patterns 130 farthest from the second pattern 120 and an outer end of the third area R3. However, the present disclosure is not limited thereto.

The first auxiliary pattern 150 and the second auxiliary pattern 155 may be inserted based on a result of analyzing the profile of the pre-photoresist pattern 300. As described above, the number of the first auxiliary patterns 150 to be inserted may be determined based on the slope of the top surface 320S2_US of the fourth sub-portion 320S2.

As the first auxiliary pattern 150 is inserted, an area size of a portion of the second area R2 not covered with the second pattern 120 may be reduced. Similarly, as the second auxiliary pattern 155 is inserted, an area size of a portion of the third area R3 not covered with the third pattern 130 may be reduced.

Each of the first auxiliary pattern 150 and the second auxiliary pattern 155 may be embodied as, for example, a sub-resolution assist feature (SRAF). However, the technical concept of the present disclosure is not limited thereto.

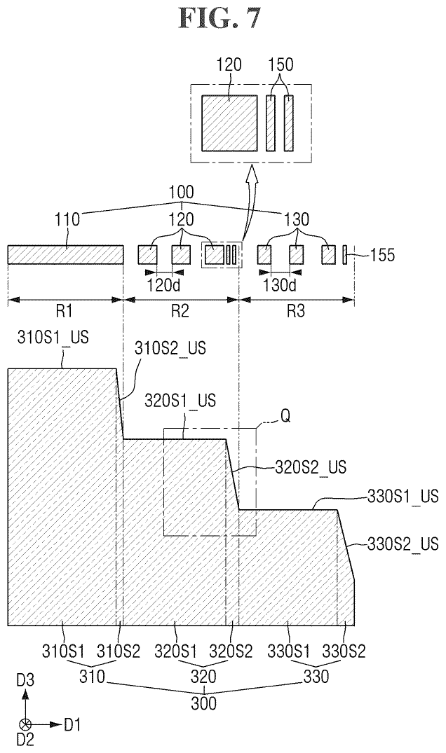

Referring to FIG. 7, the pre-photoresist pattern 300 may be re-formed using the pre-photomask 100 into which the first auxiliary pattern 150 and the second auxiliary pattern 155 have been inserted. As the first auxiliary pattern 150 is inserted, the slope of the top surface 320S2_US of the fourth sub-portion 320S2 may increase. Similarly, as the second auxiliary pattern 155 is inserted, the slope of the top surface 330S2_US of the sixth sub-portion 330S2 may increase.

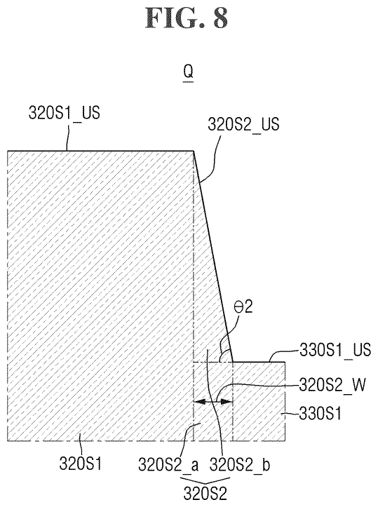

For example, referring to FIG. 8, a second angle θ2 defined between the top surface 320S2_US of the fourth sub-portion 320S2 and an extension line from the top surface 330S1_US of the fifth sub-portion 330S1 may be greater than the first angle θ1 of FIG. 5A. For reference, FIG. 8 is an enlarged view of a Q area of FIG. 7.

Further, the ratio of the relative vertical dimension H1 of the upper portion 320S2_b of the fourth sub-portion 320S2 to the width 320S2_W of the lower portion 320S2_a of the fourth sub-portion 320S2 in FIG. 8 may be greater than the ratio of the relative vertical dimension H1 of the upper portion 320S2_b of the fourth sub-portion 320S2 to the width 320S2_W of the lower portion 320S2_a of the fourth sub-portion 320S2 in FIG. 5A. As the first auxiliary pattern 150 is inserted, the second angle θ2 may be closer to 90° compared to the first angle θ1.

Similarly, as the second auxiliary pattern 155 is inserted, the slope of the top surface 330S2_US of the sixth sub-portion 330S2 may increase. Similarly, although not illustrated, the slope of the top surface of the sixth sub-portion 320S3 may increase.

In some embodiments, the number of the first auxiliary patterns 150 and the second auxiliary patterns 155 to be inserted may be determined based on sensitivity of the pre-photomask 100 to the patterning light. For example, when the pre-photomask 100 is highly sensitive to the light, the number of the first auxiliary patterns 150 and the second auxiliary patterns 155 to be inserted may be reduced. When the pre-photomask 100 is less-sensitive to the light, the number of the first auxiliary patterns 150 and the second auxiliary patterns 155 to be inserted may increase.

In some embodiments, a fourth duty correction may be performed on at least one of the first area to the third area R1, R2, and R3 based on an analyzing result of the profile of the pre-photoresist pattern 300 in the cross-sectional view.

In at least one example, when the fourth duty correction is additionally performed on the first area R1, the width 110W of the first pattern 110 may be decreased or increased. The first pattern 110 may be partially modified or removed. For example, a size of an area in which light passes through the first area R1 may be adjusted by performing the fourth duty correction on the first area R1.

In at least one example, when the fourth duty correction is additionally performed on the second area R2, the number of second patterns 120 may be increased or the number of second patterns 120 may be decreased. Further, when the fourth duty correction is additionally performed on the second area R2, the second width 120W of the second pattern 120 may decrease or increase. Further, a spacing 120d in the first direction D1 between adjacent second patterns 120 may be decreased or increased. For example, a size of an area in which light passes through the second area R2 may be adjusted by performing the fourth duty correction on the second area R2.

In at least one example, when the fourth duty correction is additionally performed on the third area R3, the number of the third patterns 130 may be increased or the number of the third patterns 130 may be decreased. Further, when the fourth duty correction is additionally performed on the third area R3, the third width 130W of the third pattern 130 may decrease or increase. Further, the spacing 130d in the first direction D1 between adjacent third patterns 130 may be decreased or increased. For example, a size of an area in which light transmits through the third area R3 may be adjusted by performing the fourth duty correction on the third area R3.

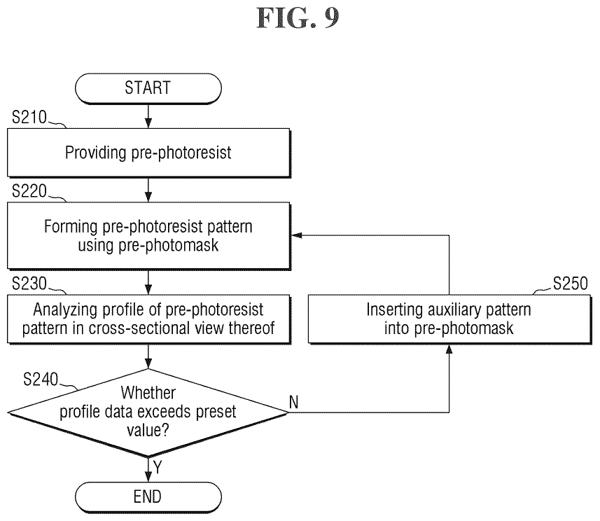

FIG. 9 is an illustrative flow chart of a method for manufacturing a photomask according to some further embodiments of the present disclosure.

Referring to FIG. 9, a method for manufacturing a photomask according to some further embodiments of the present disclosure may include providing a pre-photomask in S210, forming a pre-photoresist pattern using the pre-photomask in S220, and analyzing a profile of the pre-photoresist pattern in a cross-sectional view in S230. In FIG. 9, steps S210, S220, and S230 may be substantially similar to steps S110, S120, and S130, respectively. Thus, for brevity, in the following description repeat descriptions thereof are omitted.

Subsequently, it may be determined whether analyzed profile data of the pre-photoresist pattern exceeds a preset (or otherwise determined) value in S240. The analyzed profile data of the pre-photoresist pattern may be a slope of a top surface of the pre-photoresist pattern. For example, as described in FIG. 5A, the slope of the top surface 320S2_US of the fourth sub-portion 320S2 may be measured. In at least one example, an angle defined between the top surface 320S2_US of the fourth sub-portion 320S2 and an extension line from the top surface 330S1_US of the fifth sub-portion 330S1 may be measured. In another example, the ratio of the relative vertical dimension H1 of the upper portion 320S2_b of the fourth sub-portion 320S2 to the width 320S2_W of the lower portion 320S2_a of the fourth sub-portion 320S2 may be measured.

When the data meets and/or exceeds the preset (or otherwise determined) value, the method for manufacturing the photomask may end. At this time, the pre-photomask may be used as a photomask in a process for manufacturing a semiconductor device.

When the data does not exceed the preset (or otherwise determined) value, the auxiliary pattern may be inserted into the pre-photomask in S250. The auxiliary pattern may include the first auxiliary pattern 150 and/or the second auxiliary pattern 155 as described above. S210, S220, S230, and S240 may be repeatedly performed using the pre-photomask into which the auxiliary pattern has been inserted. For example, inserting the auxiliary pattern may include modifying the auxiliary pattern to include more or fewer of the first auxiliary pattern 150 and/or the second auxiliary pattern 155, and inserting the modified auxiliary pattern and/or modifying the inserted auxiliary pattern to match the modified auxiliary pattern. Repeatedly performing S210, S220, S230, and S240 may allow the angle defined between the top surface 320S2_US of the fourth sub-portion 320S2 and the extension line from the top surface 330S1_US of the fifth sub-portion 330S1 to be closer to 90°.

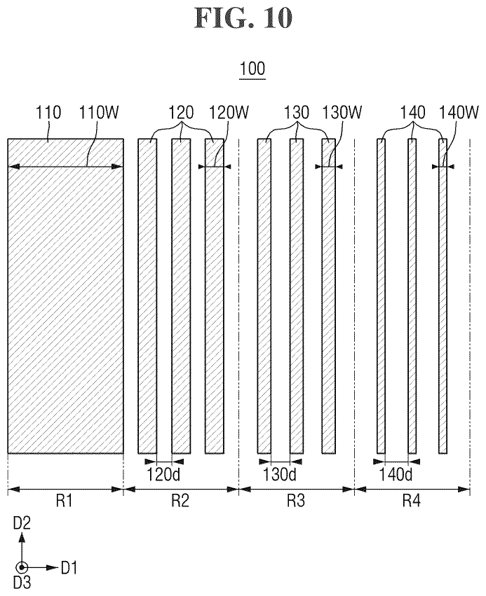

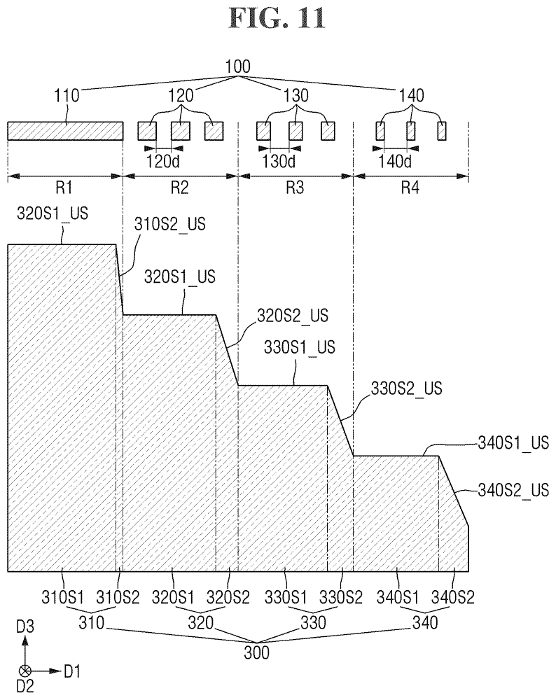

FIG. 10 and FIG. 11 are views for illustrating a method for manufacturing a photomask according to some further embodiments. For the convenience of description, following descriptions are based on differences thereof from the descriptions as set forth above with reference to FIGS. 1 to 9. For reference, FIG. 10 may be a plan view of a pre-photomask according to some further embodiments of the present disclosure, and FIG. 11 may be an illustrative cross-sectional view of a pre-photomask and a pre-photoresist pattern.

Referring to FIG. 10, the pre-photomask according to some further embodiments may further include a plurality of areas, including at least a first area R1 through a fourth area R4. The fourth area R4 may be adjacent to the third area R3. The first to fourth areas R1, R2, R3, and R4 may be sequentially arranged in the first direction D1. For example, the third area R3 may be disposed between the second area R2 and the fourth area R4, and the second area R2 may be disposed between the first area R1 and the third area R3. The fourth area R4 may be an area on which a third duty correction is performed.

The fourth area R4 may include at least one fourth patterns 140. The fourth pattern 140 does not fill an entirety of the fourth area R4. The fourth patterns 140 may be spaced apart from each other in the first direction D1. Each of the fourth patterns 140 may extend in the second direction D2.

A fourth width of 140W in the first direction D1 of each of the fourth patterns 140 is smaller than the third width of 130W in the first direction D1 of each of the third patterns 130. Further, a sum of the fourth widths 140W in the first direction D1 of the fourth patterns 140 is smaller than the sum of the third widths 130W in the first direction D1 of the third patterns 130. In other words, a size of an area not covered with the third pattern 130 is smaller than a size of an area not covered with the fourth pattern 140. Further, the spacing 130d by which the third patterns 130 are spaced from each other in the first direction D1 may be smaller than a spacing 140d by which the fourth patterns 140 are spaced from each other in the first direction D1. However, the present disclosure is not limited thereto.

Referring to FIG. 11, the pre-photoresist pattern 300 may be formed using the pre-photomask 100 of FIG. 10. The pre-photoresist pattern 300 may have a stepped shape having four steps.

The pre-photoresist pattern 300 may further include a fourth portion 340. The fourth portion 340 may be disposed on one side of the third portion 330. For example, the fourth portion 340 may be disposed on one side of the third portion 330, and the second portion 320 may be disposed on the other side of the third portion 330. The third portion 330 may be disposed between the second portion 320 and the fourth portion 340.

The fourth portion 340 of the pre-photoresist pattern 300 may be formed using the fourth area R4 of the pre-photomask 100. For example, the fourth portion 340 of the pre-photoresist pattern 300 may be formed by performing an exposure process on the fourth pattern 140. In some embodiments, the vertical dimension in the third direction D3 of the third portion 330 of the pre-photoresist pattern 300 may be greater than a vertical dimension in the third direction D3 of the fourth portion 340 of the pre-photoresist pattern 300.

In some embodiments, the fourth portion 340 may include a seventh sub-portion 340S1 having a constant vertical dimension and an eighth sub-portion 340S2 having a varying vertical dimension. For example, a vertical dimension from a bottom surface of the fourth portion 340 of the pre-photoresist pattern 300 to a top surface 340S1_US of the seventh sub-portion 340S1 of the pre-photoresist pattern 300 is constant, while a vertical dimension from the bottom surface of the fourth portion 340 of the pre-photoresist pattern 300 to a top surface 340S2_US of the eighth sub-portion 340S2 of the pre-photoresist pattern 300 is not constant. For example, the vertical dimension from the bottom surface of the fourth portion 340 of the pre-photoresist pattern 300 to the top surface 340S2_US of the eighth sub-portion 340S2 of the pre-photoresist pattern 300 may gradually decreases as the eighth sub-portion 340S2 extends away from the seventh sub-portion 34051.

In some embodiments, an analyzed profile of the pre-photoresist pattern 300 may further include the top surface 340S2_US of the eighth sub-portion 340S2. Based on the analysis result of the profile, an auxiliary pattern may be inserted into the fourth area R4 of the pre-photomask.

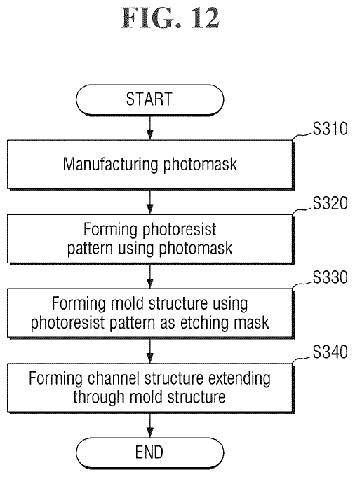

Hereinafter, a method for manufacturing a semiconductor device according to some embodiments of the present disclosure is described with reference to FIGS. 12 to 19.

FIG. 12 is an illustrative flowchart of a method for manufacturing a semiconductor device according to some embodiments of the present disclosure.

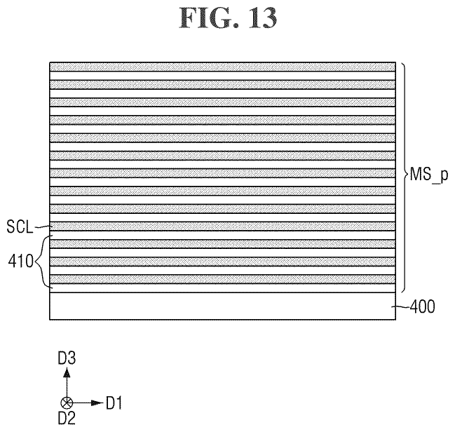

FIGS. 13 to 19 are intermediate views for illustrating a method for manufacturing a semiconductor device according to some embodiments.

First, referring to FIG. 12, a method for manufacturing a semiconductor device according to some embodiments of the present disclosure may include manufacturing a photomask in S310, forming a photoresist pattern using the photomask in S320, forming a mold structure using the photoresist pattern as an etching mask in S330, and forming a channel structure extending through the mold structure in S340.

Specifically, referring to FIG. 13, a substrate 400 may be provided. The substrate 400 may include, for example, a semiconductor substrate such as a silicon substrate, a germanium substrate, a silicon-germanium substrate, and/or the like. For example, in at least one example, the substrate 400 may include a silicon-on-insulator (SOI) substrate, a germanium-on-insulator (GOI) substrate, and/or the like. In some embodiments, the substrate 400 may contain impurities. For example, the substrate 400 may be doped with n-type impurities such as phosphorus (P), arsenic (As), and/or the like.

A pre-mold structure MS_p may be formed on the substrate 400. The pre-mold structure MS_p may include a plurality of mold insulating films 410 and a plurality of sacrificial insulating films SCL. The plurality of mold insulating films 410 and the plurality of sacrificial insulating films SCL may be alternately stacked on top of each other in the third direction D3. For example, the sacrificial insulating film SCL may be provided between mold insulating films 410 adjacent to each other in the third direction while the mold insulating film 410 may be provided between sacrificial insulating films SCL adjacent to each other in the third direction.

The mold insulating film 410 may include an insulating material, for example, at least one of silicon oxide, silicon nitride, silicon oxynitride, and/or the like. However, the present disclosure is not limited thereto. In at least one example, the mold insulating film 410 may include silicon oxide. The sacrificial insulating film SCL may include a material having an etch selectivity with respect to that of the mold insulating film 410. The sacrificial insulating film SCL may include a nitride-based insulating material. In at least one example, when the mold insulating film 410 includes silicon oxide, the sacrificial insulating film SCL may include silicon nitride.

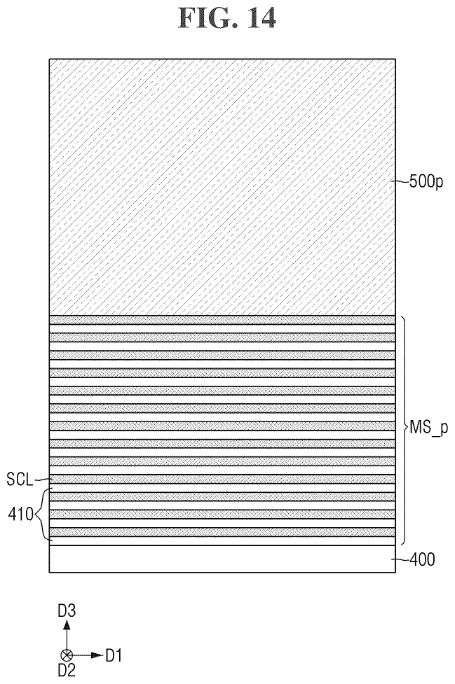

Referring to FIG. 14, a photoresist 500p may be provided. The photoresist 500p may cover an entirety of a top surface of the pre-mold structure MS_p. A vertical dimension in the third direction D3 of the photoresist 500p may be constant. However, the present disclosure is not limited thereto.

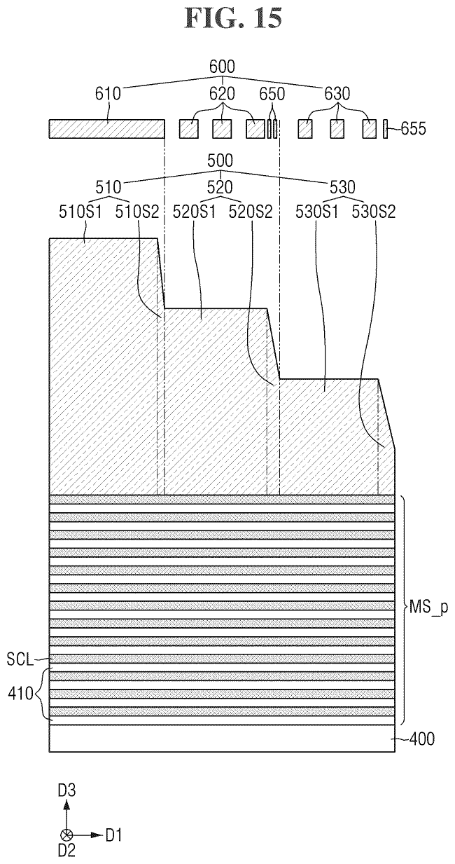

Referring to FIG. 15, a photomask 600 may be provided. The photomask 600 may be manufactured using the method for manufacturing the photomask as described with reference to FIGS. 1 to 9. A photomask 600 may be disposed on the photoresist 500p. The photomask 600 may be spaced from the photoresist 500p in the third direction D3.

The photomask 600 may include, at least, a first pattern 610, at least one second pattern 620, at least one third pattern 630, at least one first auxiliary pattern 650, and a second auxiliary pattern 655. The first pattern 610 of the photomask 600 may be a pattern on which a duty correction is not performed. The at least one second patterns 620 of the photomask 600 may be a pattern on which a first duty correction is performed. The at least one third pattern 630 of the photomask 600 may be a pattern on which a second duty correction different from the first duty correction and is performed.

In some embodiments, the first auxiliary pattern 650 of the photomask 600 may be disposed between the second pattern 620 of the photomask 600 and the third pattern 630 of the photomask 600. However, the present disclosure is not limited thereto. The second auxiliary pattern 655 of the photomask 600 may be disposed at an end of the photomask 600. However, the present disclosure is not limited thereto. The first auxiliary pattern 650 of the photomask 600 and the second auxiliary pattern 655 of the photomask 600 may be inserted using the method for manufacturing the photomask as described using FIGS. 1 to 9. The number of the first auxiliary patterns 650 and the second auxiliary patterns 655 to be inserted may vary depending on, e.g., the analysis (S130 of FIG. 1).

Subsequently, an exposure process may be performed using the photomask 600 as a mask. The exposure process may be performed to form a photoresist pattern 500. The photoresist pattern 500 may include a first portion 510, a second portion 520, and a third portion 530.

The first portion 510, the second portion 520, and the third portion 530 of the photoresist pattern 500 may be sequentially arranged in the first direction D1. The first portion 510 of the photoresist pattern 500 may be formed using the first pattern 610 of the photomask 600. The second portion 520 of the photoresist pattern 500 may be formed using the second pattern 620 and the first auxiliary pattern 650 of the photomask 600. The third portion 530 of the photoresist pattern 500 may be formed using the third pattern 630 and the second auxiliary pattern 655 of the photomask 600.

For example, the first portion 510 of the photoresist pattern 500 may be formed by performing an exposure process on the first pattern 610 of the photomask 600. The second portion 520 of the photoresist pattern 500 may be formed by performing an exposure process on the second pattern 620 and the first auxiliary pattern 650 of the photomask 600. The third portion 530 of the photoresist pattern 500 may be formed by performing an exposure process on the third pattern 630 and the second auxiliary pattern 655 of the photomask 600.

A vertical dimension in the third direction D3 of the first portion 510 of the photoresist pattern 500 is greater than a vertical dimension in the third direction D3 of the second portion 520 of the photoresist pattern 500. Further, the vertical dimension in the third direction D3 of the second portion 520 of the photoresist pattern 500 is greater than a vertical dimension in the third direction D3 of the third portion 530 of the photoresist pattern 500. For example, in a cross-sectional view, the photoresist pattern 500 may have a stepped shape.

In some embodiments, the first portion 510 of the photoresist pattern 500 may include a first sub-portion 510S1 having a constant vertical dimension and a second sub-portion 510S2 having a varying vertical dimension. For example, a vertical dimension from a bottom surface of the first portion 510 of the photoresist pattern 500 to a top surface of the second sub-portion 510S2 of the photoresist pattern 500 may gradually decrease as the second sub-portion 510S2 extends in a direction from the first sub-portion 510S1 of the first portion 510 of the photoresist pattern 500 to the second portion 520 thereof.

The second portion 520 of the photoresist pattern 500 may include a third sub-portion 520S1 having a constant vertical dimension and the fourth sub-portion 520S2 having a varying vertical dimension. For example, a vertical dimension from a bottom surface of the second portion 520 of the photoresist pattern 500 to a top surface of the fourth sub-portion 520S2 of the photoresist pattern 500 may gradually decrease as the fourth sub-portion 520S2 extends in a direction from the first portion 510 of the photoresist pattern 500 to the third portion 530 thereof.

The third portion 530 of the photoresist pattern 500 may include a fifth sub-portion 530S1 having a constant vertical dimension and a sixth sub-portion 530S2 having a varying vertical dimension. For example, a vertical dimension from a bottom surface of the third portion 530 of the photoresist pattern 500 to a top surface of the sixth sub-portion 530S2 of the photoresist pattern 500 may gradually decrease as the sixth sub-portion 530S2 extends away from the second portion 520 of the photoresist pattern 500.

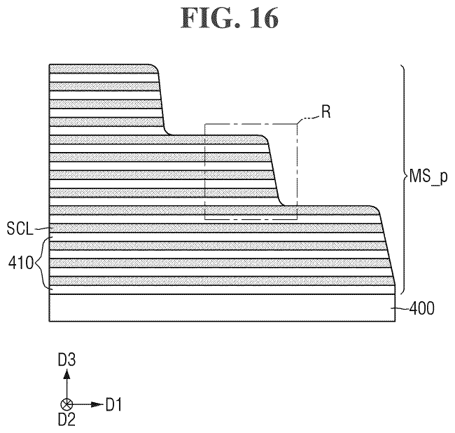

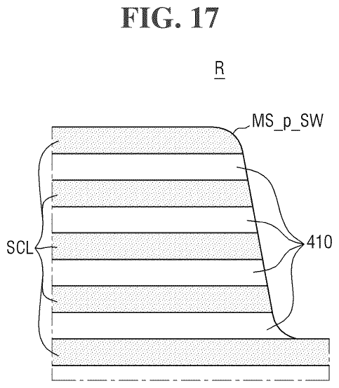

Referring to FIGS. 16 and 17, the pre-mold structure MS_p may be etched using the photoresist pattern 500 as an etching mask. The etched pre-mold structure MS_p may have a stepped shape in a cross-sectional view. For example, the etched pre-mold structure MS_p may have a stepped shape having three steps in a cross-sectional view.

In some embodiments, a corner of the pre-mold structure MS_p may be curved. Further, a sidewall MS_p_SW of the pre-mold structure MS_p may not extend in the third direction D3. The sidewall MS_p_SW of the pre-mold structure MS_p may extend in any direction between the first direction D1 and the third direction D3.

For example, each of one end and the other end in the third direction of the sidewall MS_p_SW of the pre-mold structure MS_p may be curved. A middle portion in the third direction of the sidewall MS_p_SW of the pre-mold structure MS_p may extend in any direction between the first direction D1 and the third direction D3.

This may be due to the shape of the photoresist pattern 500. Since a top surface of the second portion 520 of the photoresist pattern 500 extends in any direction between the first direction D1 and the third direction D3, the sidewall MS_p_SW of the pre-mold structure MS_p may extend in any direction between the first direction D1 and the third direction D3. However, the present disclosure is not limited thereto.

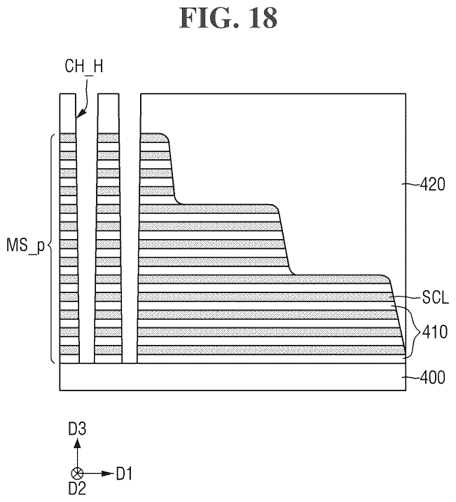

Referring to FIG. 18, an interlayer insulating film 420 covering the pre-mold structure MS_p may be formed. The interlayer insulating film 420 may include an insulating material such as an oxide-based insulating material. The interlayer insulating film 420 may include, for example, at least one of silicon oxide, silicon oxynitride, and/or a low dielectric constant (low-k) material having a lower dielectric constant than that of silicon oxide. However, the present disclosure is not limited thereto.

Subsequently, a channel hole CH_H extending through the interlayer insulating film 420 and the pre-mold structure MS_p may be formed. The channel hole CH_H may expose the sacrificial insulating films SCL and the mold insulating films 410.

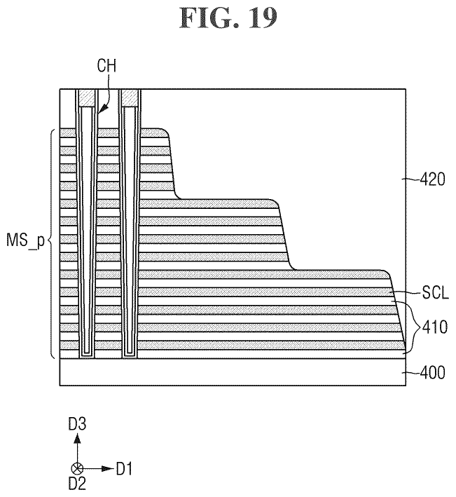

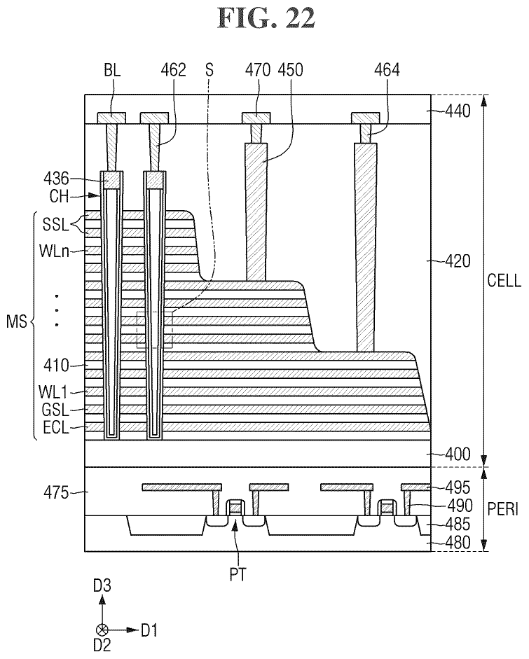

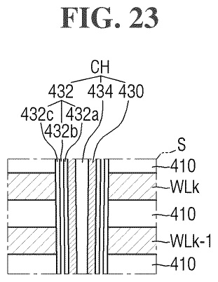

Referring to FIG. 19, a channel structure CH may be formed in the channel hole CH_H. A detailed description of the channel structure CH will be described later with reference to FIGS. 22 and 23.

Subsequently, the sacrificial insulating films SCL may be removed, and a plurality of gate electrodes may be respectively formed in spaces obtained via the removal of the sacrificial insulating films SCL.

Hereinafter, a semiconductor device manufactured using a method for manufacturing a semiconductor device according to some embodiments of the present disclosure is described. Although the semiconductor device is illustrated as being embodied as a flash memory device, the present disclosure is not limited thereto.

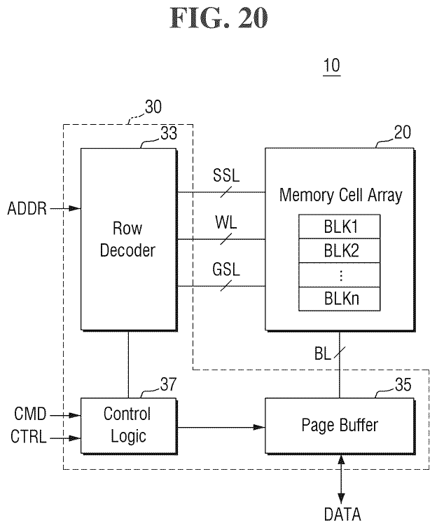

FIG. 20 is an illustrative block diagram for illustrating a semiconductor device in accordance with some embodiments.

Referring to FIG. 20, a semiconductor device 10 according to some embodiments includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 via a bit-line BL, a word-line WL, at least one string select line SSL and at least one ground select line GSL. For example, the memory cell blocks BLK1 to BLKn may be connected to a row decoder 33 via the word-line WL, the string select line SSL, and the ground select line GSL. Further, the memory cell blocks BLK1 to BLKn may be connected to a page buffer 35 via the bit-line BL.

The peripheral circuit 30 may receive an address ADDR, a command CMD, and a control signal CTRL from an external device to the semiconductor device 10, and may transmit and receive data DATA to and from an external device to the semiconductor device 10. The peripheral circuit 30 may include a control logic 37, a row decoder 33 and a page buffer 35. Although not shown, the peripheral circuit 30 includes various sub-circuits such as an input/output circuit, a voltage generation circuit for generating various voltages required for an operation of the semiconductor device 10, an error correction circuit for correcting an error in the data DATA read from the memory cell array 20, etc.

The control logic 37 may be connected to the row decoder 33, the input/output circuit and the voltage generation circuit. The control logic 37 may control overall operations of the semiconductor device 10. The control logic 37 may generate various internal control signals used in the semiconductor device 10 in response to the control signal CTRL. For example, the control logic 37 may adjust a voltage level provided to each of the word-line WL and the bit-line BL in performing a memory operation such as a program operation or an erase operation.

The row decoder 33 may select at least one of the plurality of memory cell blocks BLK1 to BLKn in response to the address ADDR, and may select at least one word-line WL, at least one string select line SSL, and at least one ground select line GSL of the selected at least one memory cell block BLK1 to BLKn. Further, the row decoder 33 may transmit a voltage for performing a memory operation to the word-line WL of the selected at least one memory cell block BLK1 to BLKn.

The page buffer 35 may be connected to the memory cell array 20 via the bit-line BL. The page buffer 35 may operate as a writer driver or a sense amplifier. Specifically, when performing a program operation, the page buffer 35 operates as the writer driver to apply a voltage based on the data DATA to be stored in the memory cell array 20 to the bit-line BL. On the other hand, when performing a read operation, the page buffer 35 may operate as the sense amplifier to detect the data DATA stored in the memory cell array 20.

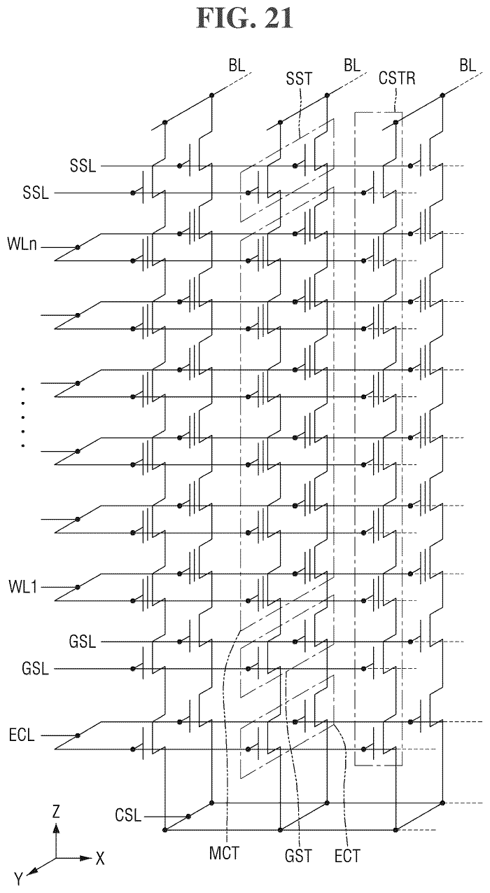

FIG. 21 is an illustrative circuit diagram for illustrating a semiconductor device according to some embodiments.

Referring to FIG. 21, a memory cell array (for example, 20 in FIG. 20) of a semiconductor device according to some embodiments includes a common source line CSL, a plurality of bit-lines BL, and a plurality of cell strings CSTR.

The common source line CSL may extend in a first direction X. In some embodiments, a plurality of common source lines CSL may be arranged two-dimensionally. For example, the plurality of common source lines CSL may be spaced apart from each other and may extend in the first direction X. The same voltage may be applied to the common source lines CSL, or different voltages may be applied thereto such that the common source lines CSL may be controlled separately.

The plurality of bit-lines BL may be two-dimensionally arranged in a plane defined by the first direction X and a second direction Y intersecting the first direction X. For example, the bit-lines BL may be arranged and spaced apart from each other in the first direction X and may extend in the second direction Y intersecting the first direction X. The plurality of cell strings CSTR may be connected in parallel to each of the bit-lines BL. The cell strings CSTR may be commonly connected to the common source line CSL. For example, the plurality of cell strings CSTR may be disposed between the bit-lines BL and the common source line CSL.

Each of the cell strings CSTR may include a ground select transistor GST connected to the common source line CSL, a string select transistor SST connected to the bit-line BL, and a plurality of memory cell transistors MCT disposed between the ground select transistor GST and the string select transistor SST. Each of the memory cell transistors MCT may include a data storage element. The ground select transistor GST, the string select transistor SST and the memory cell transistors MCT may be connected in series to each other in a third direction Z.

The common source line CSL may be commonly connected to sources of the ground select transistors GST. Further, a ground select line GSL, a plurality of word-lines WL11 to WL1n, and a string select line SSL may be disposed between the common source line CSL and the bit-line BL. The ground select line GSL may act as a gate electrode of the ground select transistor GST. The word-lines WL11 to WL1n may be respectively used as gate electrodes of the memory cell transistors MCT. The string select line S SL may act as a gate electrode of the string select transistor SST/. The plurality of word-lines WL1 to WLn may be stacked in a Z direction Z intersecting the first direction X and the second direction Y.

In some embodiments, an erase control transistor ECT may be disposed between the common source line CSL and the ground select transistor GST. The common source line CSL may be commonly connected to sources of the erase control transistors ECT. Further, an erase control line ECL may be disposed between the common source line CSL and the ground select line GSL. The erase control line ECL may be used as a gate electrode of the erase control transistor ECT. The erase control transistors ECT may cause GIDL (Gate Induced Drain Leakage) to perform an erase operation of the memory cell array.

FIG. 22 is an illustrative cross-sectional view for illustrating a semiconductor device according to some embodiments. FIG. 23 is an enlarged view of an S area in FIG. 22. Referring to FIGS. 22 and 23, a semiconductor device according to some embodiments includes a cell structure CELL (e.g., the memory cell array 20 of FIG. 20) and a peripheral circuit structure PERI (e.g., the peripheral circuit 30 of FIG. 20).

The cell structure CELL may include a substrate 400, a mold structure MS, interlayer insulating film 420, a channel structure CH, a bit-line BL, a cell contact 450, and a first inter-wiring insulating film 440.

The substrate 400 may include, for example, a semiconductor substrate such as a silicon substrate, a germanium substrate, a silicon-germanium substrate, and/or the like. In at least one example, the substrate 400 may include a silicon-on-insulator (SOI) substrate or a germanium-on-insulator (GOI) substrate. In some embodiments, the substrate 400 may contain impurities. For example, the substrate 400 may be doped with n-type impurities such as phosphorus (P), arsenic (As), and the like.

A memory cell array CELL including a plurality of memory cells may be disposed on the substrate 400. A channel structure CH, a bit-line BL, and gate electrodes ECL, GSL, WL1 to WLn, and SSL, and the like as described later may be disposed on the substrate 400. In following descriptions, a surface of the substrate 400 on which the memory cell array is disposed may be referred to as a front surface of the substrate 400. A surface of the substrate 400 opposite the front surface of the substrate 400 may be referred to as a rear surface of the substrate 400.

The mold structure MS may be disposed on the front surface (for example, a top surface) of the substrate 400. The mold structure MS may include a plurality of gate electrodes ECL, GSL, WL1 to WLn, and SSL, and a plurality of mold insulating films 410 alternately stacked on top of each other while being disposed on the substrate 400. Each of the gate electrodes ECL, GSL, WL1 to WLn, and SSL and the mold insulating film s410 may have a layered structure extending in parallel with the top surface of the substrate 400. The gate electrodes ECL, GSL, WL1 to WLn, and SSL may be sequentially stacked on the substrate 400 while being spaced apart from each other via the mold insulating films 410.

The gate electrodes ECL, GSL, WL1 to WLn, and SSL may be stacked in a stepwise manner. For example, the gate electrodes ECL, GSL, WL1 to WLn, and SSL may extend so as to have different extension lengths and thus may be stacked in the stepwise manner. Accordingly, each of the gate electrodes ECL, GSL, WL1 to WLn, and SSL may include a pad area (not shown) not covered with other gate electrodes. The pad area may refer to an area where the cell contact 450 and each of the gate electrodes contact each other.

In some embodiments, the gate electrodes ECL, GSL, WL1 to WLn, and SSL may include an erase control line ECL, a ground select line GSL, and a plurality of word-lines WL1 to WLn sequentially stacked on the substrate 400. In some further embodiments, the erase control line ECL may be omitted.

The mold insulating films 410 may be stacked in a stepped manner. For example, the mold insulating films 410 may extend so as to have different extension lengths and may be stacked in the stepwise manner.

Each of the gate electrodes ECL, GSL, WL1 to WLn, and SSL may include a conductive material, for example, a metal such as tungsten (W), cobalt (Co), nickel (Ni), molybdenum (Mo), etc., or a semiconductor material such as silicon. In at least one example, the semiconductor material may be doped with an impurity. However, the present disclosure is not limited thereto. In at least one example, each of the gate electrodes ECL, GSL, WL1 to WLn, and SSL may include tungsten (W) or molybdenum (Mo). Unlike what is illustrated, each of the gate electrodes ECL, GSL, WL1 to WLn, and SSL may have a stack structure of multi layers. For example, when each of the gate electrodes ECL, GSL, WL1 to WLn, and SSL has the stack structure of multi layers, each of the gate electrodes ECL, GSL, WL1 to WLn, and SSL may include a gate electrode barrier film and a gate electrode filling film. The gate electrode barrier film may include, for example, titanium nitride (TiN), and the gate electrode filling film may include tungsten (W). However, the present disclosure is not limited thereto. In at least one embodiment, each of the gate electrodes ECL, GSL, WL1 to WLn, and SSL may include tungsten (W), e.g., as the conductive material.

The mold insulating film 410 may include an insulating material, for example, at least one of silicon oxide, silicon nitride, or silicon oxynitride. However, the present disclosure is not limited thereto. In at least one example, the mold insulating film 410 may include silicon oxide.

In some embodiments, a stepped corner of the mold structure MS may be formed in a curved shape. However, the present disclosure is not limited thereto.

The interlayer insulating film 420 may be disposed on the substrate 400. The interlayer insulating film 420 may cover the mold structure MS. The interlayer insulating film 420 may include an oxide-based insulating material. The interlayer insulating film 420 may include, for example, at least one of silicon oxide, silicon oxynitride, and/or a low dielectric constant (low-k) material having a lower dielectric constant than that of silicon oxide. However, the present disclosure is not limited thereto.

The channel structure CH may be formed in the mold structure MS. The channel structure CH may extend in a vertical direction intersecting the top surface of the substrate 400 and extend through the mold structure MS. For example, the channel structure CH may have a pillar shape, for example, a cylinder shape. Accordingly, the channel structure CH may intersect each of the gate electrodes ECL, GSL, WL1 to WLn, and SSL.

The channel structure CH may include a semiconductor pattern 430, an information storage film 432, and a filling pattern 434.

The semiconductor pattern 430 may extend in the vertical direction and extend through the mold structure MS. The semiconductor pattern 430 is illustrated to have a shape of a cup. However, this is only an example. For example, the semiconductor pattern 430 may have various shapes, such as a cylindrical shape, a rectangular cylindrical shape, a solid pillar shape, and/or the like. The semiconductor pattern 430 may include a semiconductor material such as single crystal silicon, polycrystalline silicon, an organic semiconductor material, a carbon nanostructure, etc. However, the present disclosure is not limited thereto.

The information storage film 432 may be interposed between the semiconductor pattern 430 and each of the gate electrodes ECL, GSL, WL1 to WLn, and SSL. For example, the information storage film 432 may extend along an outer side surface of the semiconductor pattern 430. The information storage film 432 may include, for example, at least one of silicon oxide, silicon nitride, silicon oxynitride, or a high dielectric constant material having a higher dielectric constant than that of silicon oxide. The high dielectric constant material may include, for example, at least one of aluminum oxide, hafnium oxide, lanthanum oxide, tantalum oxide, titanium oxide, lanthanum hafnium oxide, lanthanum aluminum oxide, dysprosium scandium oxide, combinations thereof, and/or the like.

In some embodiments, the information storage film 432 may be composed of multiple films. For example, as shown in FIG. 23, the information storage film 432 may include a tunnel insulating film 432a, a charge storage film 432b, and a blocking insulating film 432c sequentially stacked on the outer side surface of the semiconductor pattern 430.

The tunnel insulating film 432a may include, for example, silicon oxide and/or a high dielectric constant material having a higher dielectric constant than that of silicon oxide. The high dielectric constant material may include aluminum oxide (Al₂O₃), and hafnium oxide (HfO₂). The charge storage film 432b may include, for example, silicon nitride. The blocking insulating film 432c may include, for example, silicon oxide and/or a high dielectric constant material having a higher dielectric constant than that of silicon oxide. The high dielectric constant material may include aluminum oxide (Al₂O₃), and hafnium oxide (HfO₂). The blocking insulating film 432c may electrically contact the word-lines WLk and WLk-1.

In some embodiments, the channel structure CH may further include a filling pattern 434. The filling pattern 434 may be formed to fill an inside of the cup-shaped semiconductor pattern 430. The filling pattern 434 may include an insulating material, for example, silicon oxide. However, the present disclosure is not limited thereto.

In some embodiments, the channel structure CH may further include a channel pad 436. The channel pad 436 may be formed to be connected to the semiconductor pattern 430. For example, the channel pad 436 may be disposed in the interlayer insulating film 420 so as to be connected to a top of the semiconductor pattern 430. The channel pad 436 may include, for example, polysilicon doped with impurities. However, the present disclosure is not limited thereto.

The bit-line BL may be formed on the mold structure MS and the interlayer insulating film 420. The bit-line BL may be connected to a plurality of channel structures CH. For example, a bit-line contact 462 connected to a top of each of the channel structures CH may be formed in the interlayer insulating film 420. The bit-line BL may be electrically connected to the channel structures CH via the bit-line contact 462.

The cell contact 450 may be disposed on the substrate 400. The cell contact 450 may extend in the vertical direction and extend through the interlayer insulating film 420. The cell contact 450 may be connected to an exposed topmost gate electrode among the gate electrodes ECL, GSL, WL1 to WLn, and SSL. For convenience of illustration, two cell contacts 450 are illustrated. However, the present disclosure is not limited thereto.

All of top surfaces of the plurality of cell contacts 450 may be coplanar with each other. Further, all of bottom surfaces of the plurality of cell contact 450 may be coplanar with each other. However, the present disclosure is not limited thereto.

The cell contact 450 may be connected to a first wiring pattern 470 on the interlayer insulating film 420. For example, the first inter-wiring insulating film 440 may be disposed on the interlayer insulating film 420. The first wiring pattern 470 may be formed in the first inter-wiring insulating film 440 and may be connected to the cell contact 450. The cell contact 450 and the first wiring pattern 470 may be connected to each other via a first wiring contact 464. The first wiring pattern 470 may be connected to the bit-line BL. Each of the first wiring pattern 470 and the first wiring contact 464 may include a conductive material. For example, each of the first wiring pattern 470 and the first wiring contact 464 may include a conductive material such as tungsten (W) and/or copper (Cu). However, the present disclosure is not limited thereto.

The peripheral circuit structure PERI may include a peripheral circuit substrate 480, and a peripheral circuit element PT.

The peripheral circuit substrate 480 may be disposed below the substrate 400. For example, a top surface of the peripheral circuit substrate 480 may face the bottom surface of the substrate 400. The peripheral circuit substrate 480 may include, for example, a semiconductor substrate such as a silicon substrate, a germanium substrate, a silicon-germanium substrate, and/or the like. In at least one example, the peripheral circuit substrate 480 may include a silicon-on-insulator (SOI) substrate or a germanium-on-insulator (GOI) substrate, etc.

The peripheral circuit element PT may be formed on the peripheral circuit substrate 480. The peripheral circuit element PT may constitute a peripheral circuit that controls an operation of the semiconductor device. For example, the peripheral circuit element PT may include a control logic (for example, 37 of FIG. 20), a row decoder (for example, 33 of FIG. 20), and a page buffer (for example, 35 of FIG. 20), etc. In following descriptions, a surface of the peripheral circuit substrate 480 on which the peripheral circuit element PT is disposed may be referred to as a front surface (front side) of the peripheral circuit substrate 480. Conversely, a surface of the peripheral circuit substrate 480 opposite to the front surface of the peripheral circuit substrate 480 may be referred to as a rear surface (back side) of the peripheral circuit substrate 480.

The peripheral circuit element PT may include, for example, a transistor. However, the present disclosure is not limited thereto. For example, the peripheral circuit element PT may include not only various active elements such as a transistor, but also various passive elements such as a capacitor, a resistor, and an inductor.

In some embodiments, the rear surface of the substrate 400 may face the front surface of the peripheral circuit substrate 480. For example, a second inter-wiring insulating film 475 covering the peripheral circuit element PT may be formed on the front surface of the peripheral circuit substrate 480. The substrate 400 may be disposed on a top surface of the second inter-wiring insulating film 475.

A second wiring pattern 495 connected to the peripheral circuit element PT may be formed in the second inter-wiring insulating film 475. The second wiring pattern 495 may be connected to the peripheral circuit element PT via a second wiring contact 490. Further, the bit-line BL, and/or each of the gate electrodes ECL, GSL, WL1 to WLn, and SSL may be electrically connected to the peripheral circuit element PT via the second wiring pattern 495.

The peripheral circuit elements PT may be isolated from each other via a peripheral element isolation film 485. For example, the peripheral element isolation film 485 may be formed in the peripheral circuit substrate 480. The peripheral element isolation film 485 may be embodied as a shallow trench isolation (STI) film. The peripheral element isolation film 485 may define an active area of the peripheral circuit element PT. The peripheral element isolation film 485 may include an insulating material. The peripheral element isolation film 485 may include, for example, at least one of silicon nitride, silicon oxide, silicon oxynitride, and/or the like.

Hereinafter, referring to FIGS. 20 to 22 and FIGS. 24 to 26, an electronic system including a semiconductor device according to some embodiments will be described.

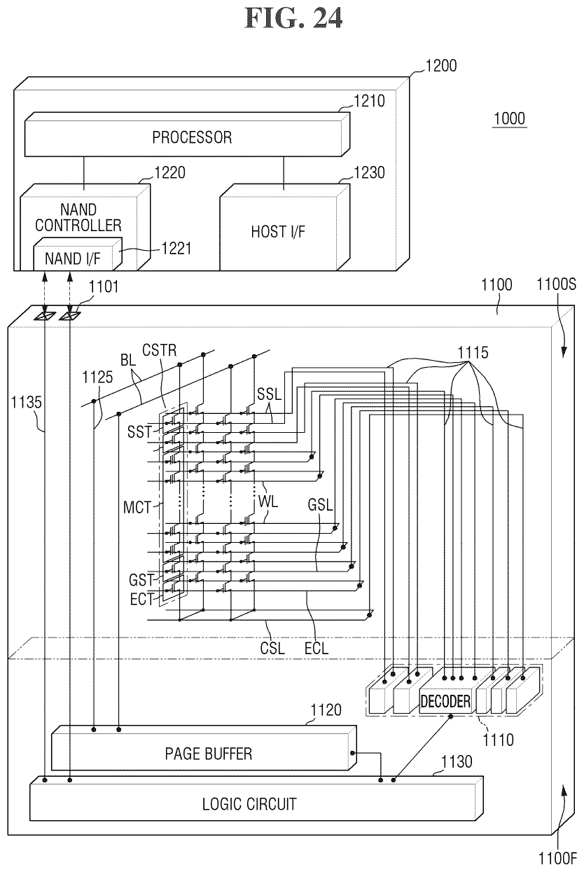

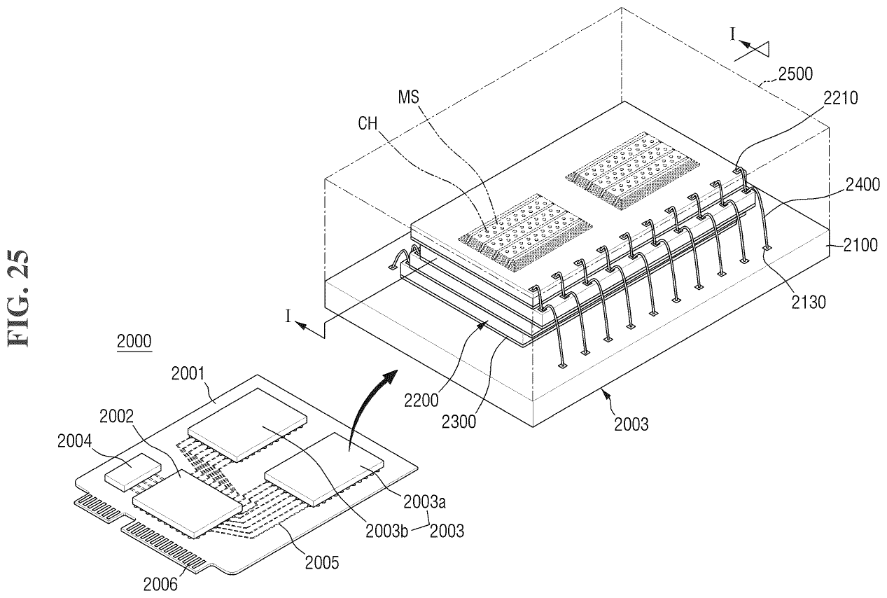

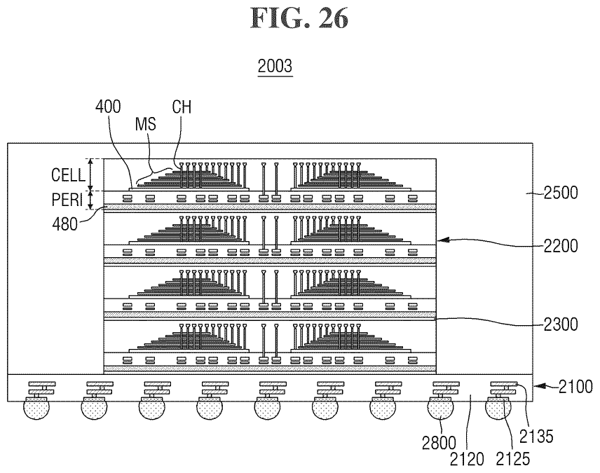

FIG. 24 is an illustrative block diagram for illustrating an electronic system in accordance with some embodiments. FIG. 25 is an illustrative perspective view for illustrating an electronic system in accordance with some embodiments. FIG. 26 is a schematic cross-sectional view taken along a line I-I in FIG. 25.

Referring to FIG. 24, an electronic system 1000 according to some embodiments may include a semiconductor device 1100 and a controller 1200 electrically connected to the semiconductor device 1100. The electronic system 1000 may be a storage device including one or a plurality of semiconductor devices 1100 and/or an electronic device including the storage device. For example, the electronic system 1000 may be an SSD device (a solid state drive device), a USB (universal serial bus), a computing system, a medical device, a communication device, and/or the like including one or a plurality of semiconductor devices 1100.

The semiconductor device 1100 may be, for example, a NAND flash memory device, and may be, for example, the semiconductor device as described above with reference to FIGS. 20 to 22. The semiconductor device 1100 may include a first structure 1100F and a second structure 1100S disposed on the first structure 1100F.

The first structure 1100F may be a peripheral circuit structure including a decoder circuit 1110 (for example, the row decoder 33 in FIG. 20), the page buffer 1120 (for example, the page buffer 35 in FIG. 20), and a logic circuit 1130 (for example, the control logic 37 of FIG. 20).

The second structure 1100S may include the common source line CSL, the plurality of bit-lines BL, and the plurality of cell strings CSTR as described above with reference to FIG. 21. The cell strings CSTR may be connected to the decoder circuit 1110 via the word-line WL, at least one string select line SSL, and at least one ground select line GSL. Further, the cell strings CSTR may be connected to the page buffer 1120 via the bit-lines BL.

In some embodiments, the common source line CSL and the cell strings CSTR may be electrically connected to the decoder circuit 1110 via first connection lines 1115 extending from the first structure 1100F to the second structure 1100S.

In some embodiments, the bit-lines BL may be electrically connected to the page buffer 1120 via second connection lines 1125 extending from the first structure 1100F to the second structure 1100S.

The semiconductor device 1100 may communicate with the controller 1200 via an input/output pad 1101 electrically connected to the logic circuit 1130 (e.g., the control logic 37 in FIG. 20). The input/output pad 1101 may be electrically connected to the logic circuit 1130 via an input/output connection line 1135 extending from the first structure 1100F to the second structure 1100S.

The controller 1200 may include a processor 1210, a NAND controller 1220, and a host interface 1230. In some embodiments, the electronic system 1000 may include a plurality of semiconductor devices 1100. In these cases, the controller 1200 may control the plurality of semiconductor devices 1100.

The processor 1210 may control overall operations of the electronic system 1000 including the controller 1200. The processor 1210 may operate based on predefined firmware, and may control the NAND controller 1220 to access the semiconductor device 1100. The NAND controller 1220 may include a NAND interface 1221 that processes communication with the semiconductor device 1100. Via the NAND interface 1221, a control command for controlling the semiconductor device 1100, data to be written to memory cell transistors MCT of the semiconductor device 1100, and data to be read from the memory cell transistors MCT of the semiconductor device 1100 may be transmitted. The host interface 1230 may provide a communication function between the electronic system 1000 and an external host. Upon receiving a control command from an external host via the host interface 1230, the processor 1210 may control the semiconductor device 1100 in response to the control command.

Referring to FIGS. 24 to 26, an electronic system according to some embodiments may include a main substrate 2001, a main controller 2002 mounted on the main substrate 2001, at least one semiconductor package 2003, and at least one dynamic random access memory (DRAM) 2004. The semiconductor package 2003 and the DRAM 2004 may be connected to the main controller 2002 via wiring patterns 2005 formed on the main substrate 2001.

The main substrate 2001 may include a connector 2006 including a plurality of pins coupled to an external host. The number and an arrangement of the plurality of pins in the connector 2006 may vary based on a communication interface between the electronic system 2000 and the external host. In some embodiments, the electronic system 2000 may communicate with the external host using one of interfaces such as USB (Universal Serial Bus), PCI-Express (Peripheral Component Interconnect Express), SATA (Serial Advanced Technology Attachment), M-Phy for UFS (Universal Flash Storage), etc. In some embodiments, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may improve an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a bottom surface of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may correspond to the input/output pad 1101 in FIG. 24.

In some embodiments, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In some embodiments, in each of the first semiconductor package 2003a and the second semiconductor package 2003b, the semiconductor chips 2200 may be electrically connected to each other via a connection structure including a through electrode (Through Silicon Via: TSV) instead of the connection structure 2400 using the bonding wire scheme.

In some embodiments, the main controller 2002 and the semiconductor chips 2200 may be included in one package. In some embodiments, the main controller 2002 and the semiconductor chips 2200 may be mounted on a separate interposer substrate different from the main substrate 2001, and the main controller 2002 and the semiconductor chips 2200 may be connected to each other via a wiring formed in the interposer substrate.

In some embodiments, the package substrate 2100 may be embodied as a printed circuit board. The package substrate 2100 may include a package substrate body 2120, the package upper pads 2130 disposed on a top surface of the package substrate body 2120, package lower pads 2125 disposed on a bottom surface of the package substrate body 2120, or exposed through the bottom surface thereof, and internal lines 2135 disposed in the package substrate body 2120 so as to electrically connect the upper pads 2130 and the lower pads 2125 to each other. The upper pads 2130 may be electrically connected to the connection structures 2400. The lower pads 2125 may be connected to the wiring patterns 2005 of the main substrate 2001 of the electronic system 2000 via conductive connectors 2800 as shown in FIG. 25.

Referring to FIGS. 25 and 26, in the electronic system according to some embodiments, each of the semiconductor chips 2200 may include the semiconductor device as described above with reference to FIGS. 20 to 22. For example, each of the semiconductor chips 2200 may include the peripheral circuit structure PERI and the cell structure CELL stacked on the peripheral circuit structure PERI. By way of example, the peripheral circuit structure PERI may include the peripheral circuit substrate 480 and the peripheral circuit element PT as described above with reference to FIG. 22. Further, by way of example, the cell structure CELL may include the substrate 400, the mold structure MS, the channel structure CH, the bit-line BL, and the cell contact 450 as described above with reference to FIG. 22.

Although some embodiments of the present disclosure have been described above with reference to the accompanying drawings, the present disclosure may not be limited to the example embodiments and may be implemented in various different forms. Those of ordinary skill in the technical field to which the present disclosure belongs will be able to understand that the present disclosure may be implemented in other specific forms without changing the technical idea or essential features of the present disclosure. Therefore, it should be understood that the embodiments as described above are not restrictive but illustrative in all respects.

What is claimed is:

1. A method for manufacturing a photomask, the method comprising:
providing a pre-photomask, the pre-photomask including a first area, a second area configured to perform a first duty correction, and a third area configured to perform a second duty correction;
forming a pre-photoresist pattern using the pre-photomask such that the pre-photoresist pattern has a stepped shape having at least three steps in a cross-sectional view of the pre-photoresist pattern;
analyzing a profile of the pre-photoresist pattern in the cross-sectional view; and
inserting an auxiliary pattern into at least one of the first to third areas, based on a result of the analyzing of the profile of the pre-photoresist pattern.

2. The method of claim 1, wherein the pre-photoresist pattern is formed to include first to third portions sequentially arranged,
wherein the first portion is formed using the first area,
wherein the second portion is formed using the second area, and
wherein the third portion is formed using the third area.

3. The method of claim 2, wherein the second portion includes a first sub-portion and a second sub-portion sequentially arranged in a first direction between the first portion and the third portion,
the first sub-portion having a constant vertical dimension as the first sub-portion extends in the first direction, and
the second sub-portion having a varying vertical dimension as the second sub-portion extends in the first direction .

4. The method of claim 3, wherein the auxiliary pattern is inserted into a portion of the second area corresponding to the second sub-portion.

5. The method of claim 3, wherein
the inserted auxiliary pattern includes one or more auxiliary patterns,
the second sub-portion includes
an upper portion, and
a lower portion under the upper portion such that the lower portion overlaps
with the third portion in the first direction, and
wherein the inserting the auxiliary pattern includes determining a number of auxiliary patterns to be inserted based on a width in the first direction of the upper portion, and a height of the upper portion.

6. The method of claim 1, further comprising:
performing a fourth duty correction on at least one of the first to third areas based on the result of the analyzing the profile of the pre-photoresist pattern.

7. The method of claim 1, wherein the pre-photomask further includes a fourth area performed a third duty correction, and the stepped shape has at least four steps in the cross-sectional view.

8. The method of claim 1, wherein
the inserted auxiliary pattern includes one or more auxiliary patterns, and
the inserting the auxiliary pattern includes determining a number of auxiliary patterns to be inserted based on a sensitivity of the pre-photomask to light.

9. A method for manufacturing a photomask, the method comprising:
providing a pre-photoresist;
providing a pre-photomask over the pre-photoresist, the pre-photomask including at least a first area configured to perform a first duty correction and a second area configured to perform a second duty correction;
performing an exposure process on the pre-photoresist using the pre-photomask to form a pre-photoresist pattern, wherein the pre-photoresist pattern includes a first portion formed using the first area and a second portion formed using the second area such that, in a cross-sectional view of the pre-photoresist pattern, the first area includes a first sub-portion having a constant vertical dimension, and a second sub-portion having a varying vertical dimension;
analyzing a profile of the second sub-portion of the pre-photoresist pattern; and
inserting an auxiliary pattern into the first area based on a result of the analyzing the profile of the second sub-portion.

10. The method of claim 9, wherein
the inserted auxiliary pattern includes one or more auxiliary patterns,
wherein inserting the auxiliary pattern includes determining a number of the auxiliary patterns to be inserted based on a slope of a top surface of the second sub-portion.

11. The method of claim 10, further comprising:
repeating the exposure process, the analyzing the profile, and inserting the auxiliary pattern until the slope of the top surface of the second sub-portion is smaller than a set value.

12. The method of claim 9, wherein the auxiliary pattern is inserted into a portion of the first area corresponding to the second sub-portion.

13. The method of claim 9, wherein
the inserted auxiliary pattern includes one or more auxiliary patterns,
wherein the inserting the auxiliary pattern includes determining a number of the auxiliary patterns to be inserted based on a sensitivity of the pre-photomask to light.

14. The method of claim 9, further comprising:
performing a fourth duty correction on the first area based on the result of the analyzing the profile of the second sub-portion.

15. The method of claim 9, wherein the pre-photoresist pattern is formed to have a stepped shape having at least three steps in the cross-sectional view.

16. A method for manufacturing a semiconductor device, the method comprising:
manufacturing a photomask;
forming a photoresist pattern using the photomask such that the photoresist pattern has a stepped shape having at least three steps in a cross-sectional view of the photoresist pattern;
forming a step-shaped mold structure using the photoresist pattern as an etching mask, wherein the mold structure includes a plurality of mold insulating films and a plurality of gate electrodes alternately stacked on top of each other; and
forming a channel structure extending through the mold structure and connected to the gate electrodes,
wherein the manufacturing of the photomask includes
providing a pre-photomask including a first area, a second area configured to perform first duty correction, and a third area configured to perform a second duty correction,
forming a pre-photoresist pattern using the pre-photomask such that the pre-photoresist pattern has a stepped shape having at least three steps in a cross-sectional view of the pre-photoresist pattern,
analyzing a profile of the pre-photoresist pattern in the cross-sectional view
inserting an auxiliary pattern into at least one of the first to third areas based on a result of the analyzing of the profile of the pre-photoresist pattern, and
performing a fourth duty correction on at least one of the first to third areas using the pre-photoresist pattern with the inserted auxiliary pattern.

17. The method of claim 16, wherein the pre-photoresist pattern is formed to include first to third portions sequentially arranged,
wherein the first portion is formed using the first area,
wherein the second portion is formed using the second area, and
wherein the third portion is formed using the third area.

18. The method of claim 17, wherein the second portion includes a first sub-portion and a second sub-portion sequentially arranged in a first direction between the first portion and the third portion,
the first sub-portion having a constant vertical dimension as the first sub-portion extends in the first direction,
the second sub-portion having a varying vertical dimension as the second sub-portion extends in the first direction, and
the auxiliary pattern is inserted into a portion of the second area corresponding to the second sub-portion.

19. The method of claim 18, wherein
the inserted auxiliary pattern includes one or more auxiliary patterns,
wherein the second sub-portion includes
an upper portion, and
a lower portion under the upper portion such that the lower portion overlaps
with the third portion in the first direction, and
wherein the inserting the auxiliary pattern includes determining a number of auxiliary patterns to be inserted based on a width in the first direction of the upper portion, and a height of the upper portion.

20. The method of claim 18, wherein
the inserted auxiliary pattern includes one or more auxiliary patterns, and
the inserting the auxiliary pattern includes determining a number of auxiliary patterns to be inserted based on a sensitivity of the pre-photomask to light.
